(19) United States
(12) Patent Application Publication
(10) Pub. No.: US 2006/0044232 A1
(43) Pub. Date: Mar. 2, 2006

(54) Organic light emitting diode display and manufacturing method thereof

(76) Inventors: Beohm-Rock Choi, Seoul (KR); Hee-Hwan Choe, Incheon-si (KR); Chong-Chul Chai, Seoul (KR)

Correspondence Address: MCGUIREWOODS, LLP, 1750 TYSONS BLVD, SUITE 1800, MCLEAN, VA, 22102, US

(21) Appl. No.: 11/210,743

(22) Filed: Aug. 25, 2005

(30) Foreign Application Priority Data
Aug. 26, 2004 (KR) 10-2004-0067579

(51) Int. Cl. G09G 3/30

(52) U.S. Cl. 345/76

(57) ABSTRACT

An organic light emitting diode display including a light emitting element, a first conductive line, a second conductive line, and a third conductive line separated from one another, and a first thin film transistor coupled to the third conductive line and the light emitting element and a second thin film transistor coupled to the first conductive line and the second conductive line. A third thin film transistor includes a first electrode and a fourth thin film transistor includes a second electrode, and the first electrode and the second electrode are coupled to each other through a first contact hole in a first insulating layer.

### CROSS-REFERENCE TO RELATED APPLICATION

This application claims priority to and the benefit of Korean Patent Application No. 10-2004-0067579, filed on Aug. 26, 2004, which is hereby incorporated by reference for all purposes as if fully set forth herein.

### BACKGROUND OF THE INVENTION

1. Field of the Invention

The present invention relates to an organic light emitting diode display and a manufacturing method thereof.

2. Discussion of the Background

Display devices are playing an increasingly important role as various electronic display devices are widely used in various industries.

Generally, display devices transmit information to humans in the form of optical images, and they provide an interface between humans and electronic devices.

Display devices that display information by light emission are referred to as emissive display devices, while those displaying information by light modulation such as reflection, scattering, interference, etc., are referred to as non-emissive display devices. The emissive display devices include cathode ray tubes (CRT), plasma display panels (PDP), light emitting diodes (LED), and organic light emitting diode (OLED) displays. Non-emissive display devices include liquid crystal displays (LCD), electrochemical displays (ECD), and electrophoretic image displays (EPID).

The self-emissive OLED display displays images by exciting an organic material to emit light. The OLED display includes an anode (hole injection electrode), a cathode (electron injection electrode), and an organic light emission layer interposed therebetween. When holes and electrons are injected into the light emission layer, they recombine to form excitons, which emit light when transitioning from an excited state to a ground state.

The display includes a plurality of pixels arranged in a matrix, and each pixel includes an anode, a cathode, and a light emission layer. The pixels may be driven in passive matrix (or simple matrix) addressing or active matrix addressing.

The active matrix OLED display typically includes a switching transistor, a driving transistor, and a storage capacitor in each pixel, as well as an anode, a cathode, and a light emission layer. The driving transistor receives a data voltage from the switching transistor and drives a current having a magnitude corresponding to the difference between the data voltage and a predetermined voltage such as a supply voltage. The current from the driving transistor enters the light emission layer to cause light emission having intensity depending on the current. The driving transistor continuously drives current to maintain the emission state.

However, the driving transistor's threshold voltage may shift when a control voltage is applied for a long time, which changes the current driven by the driving transistor, thereby varying the luminance of the light emitting element. In order to solve this problem, several transistors may be utilized in one pixel. However, increasing the number of transistors per pixel decreases the aperture ratio and increases the pixel's complexity. The decreased aperture ratio may be particularly severe for a high resolution display device.

### SUMMARY OF THE INVENTION

The present invention provides an OLED display having an increased aperture ratio by decreasing an area occupied by transistors.

Additional features of the invention will be set forth in the description which follows, and in part will be apparent from the description, or may be learned by practice of the invention.

The present invention discloses a light emitting diode display including a light emitting element, a first conductive line, a second conductive line, and a third conductive line separated from one another, and a first thin film transistor coupled to the third conductive line and the light emitting element and a second thin film transistor coupled to the first conductive line and the second conductive line. A third thin film transistor includes a first electrode and a fourth thin film transistor includes a second electrode, and the first electrode and the second electrode are coupled to each other through a first contact hole in a first insulating layer.

The present invention also discloses a thin film panel including a substrate, a first conductive layer formed on the substrate, a first insulation layer formed on the first conductive layer, a second conductive layer formed on the first insulation layer, and a second insulation layer formed on the second conductive layer. A contact hole is formed in the first insulation layer and the second insulation layer to expose at least a portion of the first conductive layer and at least a portion of the second conductive layer. A third conductive layer is formed in the contact hole and couples the first conductive layer to the second conductive layer.

The present invention also discloses a method for manufacturing an organic light emitting diode display. The method includes forming a first gate electrode and a second gate electrode on a substrate, forming a first insulator on the first gate electrode and the second gate electrode, forming a first semiconductor and a second semiconductor on the first insulator, the first semiconductor and the second semiconductor overlapping the first gate electrode and the second gate electrode, respectively. A first source electrode and a first drain electrode are formed on the first semiconductor and spaced apart from each other, and a second source electrode and a second drain electrode are formed on the second semiconductor and spaced apart from each other. A second insulator is deposited, and the second insulator and the first insulator are etched to form a contact hole exposing the second gate electrode and the first drain electrode at least in part. A connecting member is formed coupling the second gate electrode with the first drain electrode through the contact hole.

The present invention also discloses a method for manufacturing an organic light emitting diode display including forming a first gate electrode and a second gate electrode on a substrate, forming a first insulating layer on the first gate electrode and the second gate electrode, forming a first semiconductor and a second semiconductor on the first insulating layer, the first semiconductor and the second semiconductor overlapping the first gate electrode and the second gate electrode, respectively. A contact hole is formed in the first insulating layer to expose a portion of the second gate electrode. A first drain electrode and a first source electrode are formed on the first semiconductor, and a second drain electrode and a second source electrode are formed on the second semiconductor. The first drain electrode is coupled to the second gate electrode through the contact hole.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is an equivalent circuit diagram of a pixel of an OLED display according to an embodiment of the present invention.

FIG. 2 is a layout view of an OLED display of FIG. 1.

FIG. 3 is a sectional view of the OLED display along line III-III of FIG. 2.

FIG. 4, FIG. 6, FIG. 8, FIG. 10, and FIG. 15 are layout views of the OLED display of FIG. 2 and FIG. 3 in intermediate steps of a manufacturing method thereof according to an embodiment of the present invention.

FIG. 5, FIG. 7, FIG. 9, FIG. 11 and FIG. 16 are sectional views of the OLED display along lines V-V, VII-VII, IX-IX, XI-XI and XVI-XVI of FIG. 4, FIG. 6, FIG. 8, FIG. 10, and FIG. 15, respectively.

FIG. 12, FIG. 13, and FIG. 14 show steps of a forming a contact hole according to an embodiment of the present invention.

FIG. 17 is a layout view of an OLED display according to another embodiment of the present invention.

FIG. 18 is a sectional view of the OLED display along line XVIII-XVIII of FIG. 17.

FIG. 19 is a layout view of the OLED display of FIG. 17 and FIG. 18 in an intermediate step of a manufacturing method thereof according to an embodiment of the present invention.

FIG. 20 is a sectional view of the OLED display along line XX-XX of FIG. 19.

### DETAILED DESCRIPTION OF THE ILLUSTRATED EMBODIMENTS

Embodiments of the present invention now will be described more fully hereinafter with reference to the accompanying drawings. The present invention may, however, be embodied in many different forms and should not be construed as limited to the embodiments set forth herein.

In the drawings, the thickness of layers, films, panels, regions, etc. are exaggerated for clarity. Like numerals refer to like elements throughout. It will be understood that when an element such as a layer, film, region or substrate is referred to as being “on” another element, it may be directly on the other element or intervening elements may also be present. In contrast, when an element is referred to as being “directly on” another element, there are no intervening elements present.

Now, OLED displays and manufacturing methods thereof according to embodiments of the present invention will be described with reference to accompanying drawings.

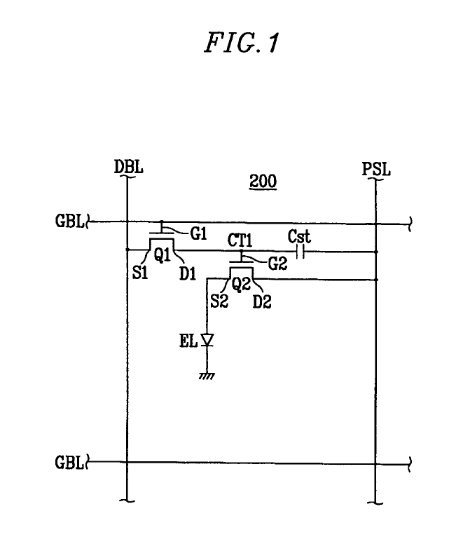

First, an OLED display according to an embodiment of the present invention is described in detail with reference to FIG. 1, which is an equivalent circuit diagram of a pixel of an OLED display according to an embodiment of the present invention.

Referring to FIG. 1, an OLED display 200 may include a plurality of gate bus lines GBL, a plurality of data bus lines DBL, a plurality of voltage transmission lines PSL, and a plurality of pixels connected thereto and arranged substantially in a matrix.

The gate bus lines GBL transmit gate signals (or scanning signals) and extend substantially in a row direction and substantially parallel to each other, while the data bus lines DBL transmit data signals and extend substantially in a column direction and substantially parallel to each other.

Each pixel includes a switching transistor Q1 coupled to the gate bus line GBL and the data bus line DBL, a driving transistor Q2 and a storage capacitor Cst that are coupled to the switching transistor Q1 and the voltage transmission line PSL, and an organic light emitting element EL coupled to the driving transistor Q2.

The switching transistor Q1 has a gate terminal G1 coupled to the gate bus line GBL, a source terminal S1 coupled to the data bus line DBL, and a drain terminal D1. The driving transistor Q2 has a gate terminal G2 coupled to the switching transistor Q1, a source terminal S2 coupled to the light emitting element EL, and a drain terminal D2 coupled to the voltage transmission line PSL. Alternatively, the driving transistor's source terminal S2 may be coupled to the voltage transmission line PSL and its drain terminal D2 may be coupled to the light emitting element EL.

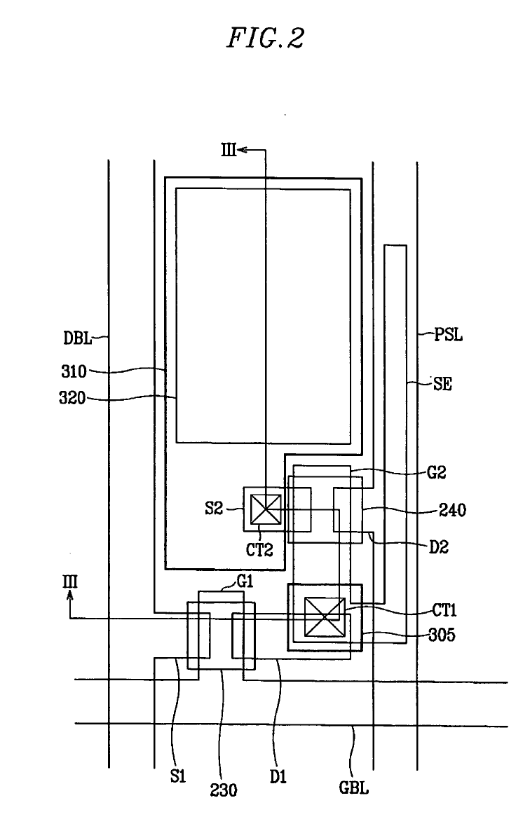

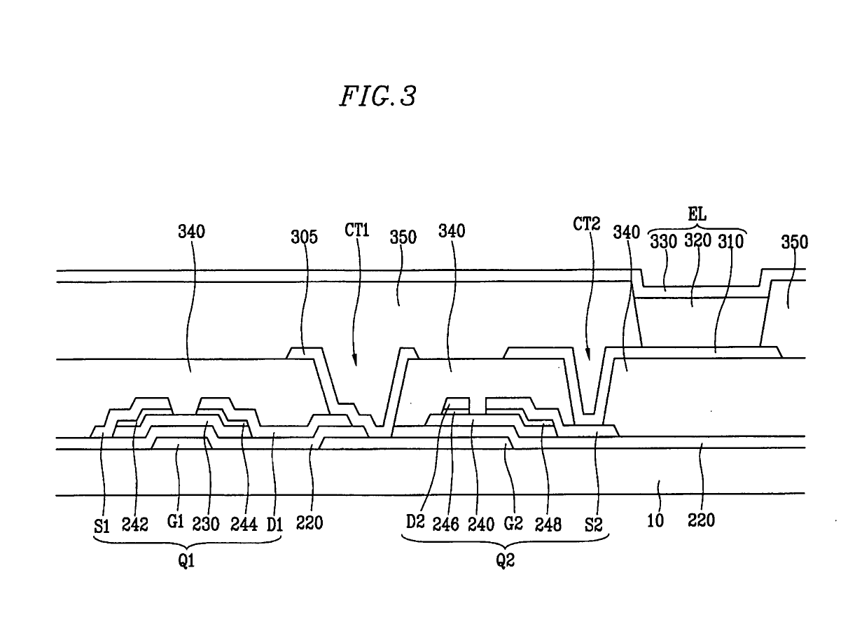

Now, a structure of an OLED display according to an embodiment of the present invention will be described in detail with reference to FIG. 1, FIG. 2 and FIG. 3.

FIG. 2 is a layout view of an OLED display of FIG. 1, and FIG. 3 is a sectional view of the OLED display along line III-III of FIG. 2.

A plurality of gate conductors that include a plurality of gate bus lines GBL having first gate electrodes G1 and a plurality of second gate electrodes G2 may be formed on an insulating substrate 10 such as transparent glass.

The gate bus lines GBL extend substantially in a transverse direction, and the first gate electrodes G1 protrude upward from the gate bus lines GBL. The gate bus lines GBL may be coupled to a driving circuit (not shown) integrated on the substrate 10, or the lines may have a large area end portion (not shown) for coupling with another layer or an external driving circuit mounted on the substrate 10 or on another device such as a flexible printed circuit film (not shown) that may be attached to the substrate 10.

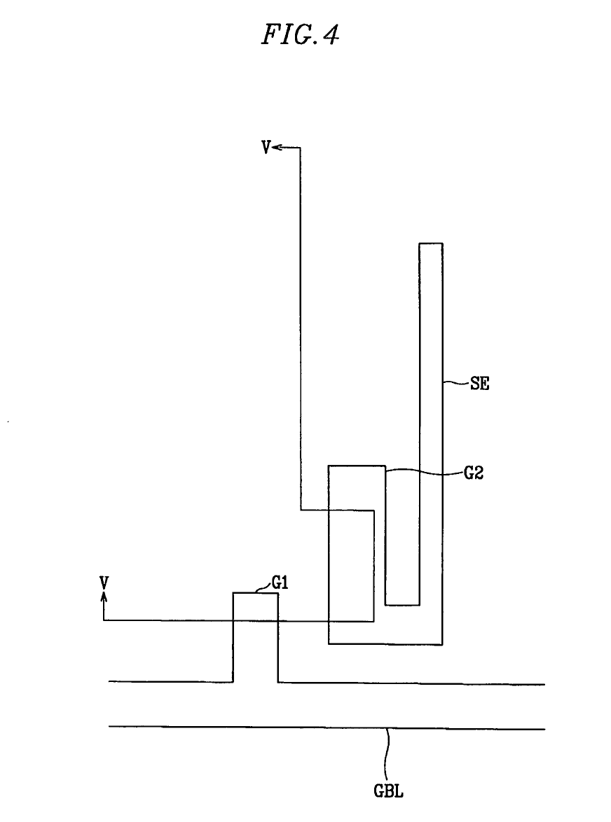

Each second gate electrode G2 is separate from the gate bus lines GBL and is arranged between two adjacent gate bus lines GBL. The second gate electrode G2 includes a storage electrode SE that extends downward, turns to the right, and then extends upward (see FIG. 4).

The gate conductors GBL and G2 may be made of, for example, Al containing a metal such as Al and Al alloy, Ag containing a metal such as Ag and Ag alloy, Cu containing a metal such as Cu and Cu alloy, Mo containing a metal such as Mo and Mo alloy, Cr, Ti or Ta. The gate conductors GBL and G2 may have a multi-layered structure including two films with different physical characteristics. One of the two films may be made of low resistivity metal, including Al containing a metal, Ag containing a metal, or Cu containing a metal, for reducing signal delay or a voltage drop in the gate conductors GBL and G2. On the other hand, the other film may be made of material such as Cr, Mo, Mo alloy, Ta, or Ti, which has good physical, chemical, and electrical contact characteristics with other materials such as indium tin oxide (ITO) or indium zinc oxide (IZO). For example, a combination of the two films may be a lower Cr film and an upper Al (alloy) film and a lower Al (alloy) film and an upper Mo (alloy) film.

Additionally, the lateral sides of the gate conductors GBL and G2 may be inclined relative to a surface of the substrate 10 at an angle of about 30-80 degrees.

A first insulating layer 220 is formed on the gate conductors GBL and G2. The first insulating layer 220 may be made of an insulator such as SiNx and SiOx or a high dielectric such as HfO₂ and Al₂O_{3.}

A plurality of first and second semiconductor islands 230 and 240, which may be made of hydrogenated amorphous silicon (“a-Si”) or polycrystalline silicon (“polysilicon”), are formed on the first insulating layer 220. The first semiconductor islands 230 are arranged on the first gate electrodes G1, and the second semiconductor islands 240 are arranged on the second gate electrodes G2.

A plurality of first and second ohmic contact islands 242 and 244 and a plurality of third and fourth ohmic contact islands 246 and 248 are arranged on the first and second semiconductor islands 230 and 240, respectively. The ohmic contact islands 242, 244, 246 and 248 are separate from each other, and they may be made of silicide or n+ hydrogenated a-Si heavily doped with an n-type impurity.

The lateral sides of the semiconductor islands 230 and 240 and the ohmic contacts 242, 244, 246 and 248 are inclined relative to a surface of the substrate at an angle of about 30-80 degrees.

A plurality of data conductors including a plurality of data bus lines DBL having first source electrodes S1, a plurality of first drain electrodes D1, a plurality of voltage transmission lines PSL having second drain electrodes D2, and a plurality of second source electrodes S2 are formed on the ohmic contacts 242, 244, 246 and 248, respectively, and the first insulating layer 220.

The data bus lines DBL transmit data signals, extend substantially in the longitudinal direction, and intersect the gate bus lines GBL. Each data bus line DBL may include a large area end portion (not shown) for coupling with another layer or an external device. The data bus lines DBL may be directly coupled to a data driving circuit (not shown) for generating the data signals, which may be integrated on the substrate 10. The first source electrodes S1 extend from the data bus lines DBL onto the first ohmic contacts 242, and the first drain electrodes D1 are arranged on the second ohmic contacts 244 such that they face the first source electrodes S1. The first drain electrodes D1 may or may not overlap the second gate electrodes G2.

The voltage transmission lines PSL transmit driving voltages Vdd and are arranged adjacent to the data bus lines DBL and extend substantially in the longitudinal direction like the data bus lines DBL. The second drain electrodes D2 extend from the voltage transmission lines PSL onto the third ohmic contacts 246. The second source electrodes S2 are arranged on the fourth ohmic contacts 248 and face the second drain electrodes D2. The voltage transmission lines PSL overlap the storage electrodes SE to form storage capacitors Cst.

A first gate electrode G1, a first source electrode S1, and a first drain electrode D1, along with a first semiconductor island 230 and a pair of first and second ohmic contacts 242 and 244, form a switching thin film transistor (TFT) Q1 having a channel formed in the semiconductor island 230 between the first source electrode S1 and the first drain electrode D1. Further, a second gate electrode G2, a second source electrode S2, and a second drain electrode D2, along with a second semiconductor island 240 and a pair of third and fourth ohmic contacts 246 and 248, form a driving TFT Q2 having a channel formed in the semiconductor island 240 between the second source electrode S2 and the second drain electrode D2.

The data conductors DBL, PSL, D1 and S2 may be made of refractory metal including Cr, Mo, Ti, Ta or alloys thereof. Further, they may have a multi-layered structure that may include a low resistivity film and a good contact film. For example, the multi-layered structure may include a triple-layered structure of a Mo (alloy) lower film, an Al (alloy) middle film, and a Mo (alloy) upper film or a dual-layered structure of a Cr/Mo (alloy) lower film and an Al (alloy) upper film.

Like the gate conductors GBL and G2, the data conductors DBL, PSL, D1 and S2 have tapered lateral sides relative to the surface of the substrate 10 at an angle of about 30-80 degrees.

The ohmic contacts 242, 244, 246 and 248 are interposed between the underlying semiconductor islands 230 and 240 and the overlying data conductors DBL, D1, PSL, and S2 thereon, and they reduce the contact resistance therebetween. The semiconductor islands 230 and 240 include a plurality of exposed portions, which are not covered with the data conductors DBL, PSL, D1 and S2.

A second insulating layer 340 is formed on the data conductors DBL, PSL, D1 and S2 and the exposed portions of the semiconductor islands 230 and 240. The second insulating layer 340 may be made of inorganic material such as silicon nitride or silicon oxide, a photosensitive or photo-insensitive organic material, or a low dielectric insulating material having a dielectric constant that is less than 4.0, such as a-Si:C:O and a-Si:O:F formed by plasma enhanced chemical vapor deposition (PECVD). The second insulating layer 340 may include a lower inorganic insulating film and an upper organic insulating film.

The second insulating layer 340 has a plurality of contact holes CT2 exposing the second source electrodes S2. The second and the first insulating layers 340 and 220 have a plurality of contact holes CT1 exposing the first drain electrodes D1 and the second gate electrodes G2 at overlapping portions of the second gate electrodes G2 and the first drain electrodes D1.

A plurality of pixel electrodes 310 and a plurality of connecting members 305 are formed on the second insulating layer 340. The pixel electrodes 310 and the connecting members 305 may be made of transparent conductive material such as IZO, ITO or amorphous ITO.

The pixel electrodes 310 are coupled to the second source electrodes S2 through the contact holes CT2, and they occupy areas enclosed by the gate bus lines GBL and the data bus lines DBL.

The connecting members 305 are disposed in the contact holes CT1 and coupled with the first drain electrodes D1 and the second gate electrodes G2. Since two conductors to be connected, i.e., the first drain electrode D1 and the second gate electrode G2, overlap each other and the contact holes CT1 are disposed at the overlapping portion to expose the two conductors, an area required for connecting the two conductors may be reduced when compared with providing contact holes on both the first drain electrodes D1 and the second gate electrodes G2. In particular, when increasing the number of the transistors to improve the characteristics of the OLED display, the area occupied by the transistors increases and the contact areas for connecting the transistors also increases, thereby decreasing aperture ratio. When the resolution of the OLED display increases, the area occupied by the pixel electrodes 310 increases to reduce the aperture ratio. However, the above-described contact structure lessens the decrease of the aperture ratio. This contact structure may be applicable not only to the coupling of the switching transistor Q1 and the driving transistor Q2, but it also may be applied to the coupling between other transistors.

An insulating bank 350 is formed on the second insulating layer 340, the pixel electrodes 310, and the connecting members 305. The bank 350 has a plurality of openings exposing portions of the pixel electrodes 310.

A plurality of organic light emitting members 320 are formed in the openings of the bank 350. Each organic light emitting member 320 includes an organic emitting layer that emits red, green, or blue light. Each organic light emitting member 320 may further include at least one of an electron transport layer, a hole transport layer, an electron injecting layer, and a hole injecting layer.

A common electrode 330 is formed on the bank 350 and the organic light emitting members 320. The common electrode 330 may be formed on the entire substrate, and it may be made of at least one of Al, Ca, Ba and Mg.

Alternatively, the pixel electrodes 310 may be made of at least one metal of Al, Ca, Ba, and Mg and the common electrode 330 may be made of transparent conductor.

The pixel electrodes 310, the organic light emitting members 320, and the common electrode 330 form organic light emitting elements EL.

In this OLED display, when the data bus line DBL is supplied with a data signal and the gate bus line GBL is supplied with a gate-on voltage for turning on the switching transistor Q1, the switching transistor Q1 transmits the data voltage of the data bus line DBL to the gate terminal (electrode) G2 of the driving transistor Q2 and to the storage electrode Cst. The driving transistor Q2 outputs current from the voltage transmission line PSL based on the voltage between its gate terminal G2 and its drain electrode D2, and the storage electrode Cst stores and maintains a voltage such that the driving transistor Q2 outputs uniform current until the next data voltage enters.

When the driving transistor Q2 outputs the current, the pixel electrode 310 injects holes into the organic light emitting member 320, and the common electrode 330 injects electrons into the organic light emitting member 320. The electrons and holes meet each other to form excitons, and the organic light emitting member 320 emits light when the excitons drop from an excited state to a ground state.

A method of manufacturing the OLED display of FIG. 2 and FIG. 3 according to an embodiment of the present invention will be now described in detail with reference to FIGS. 4-16 as well as FIG. 2 and FIG. 3.

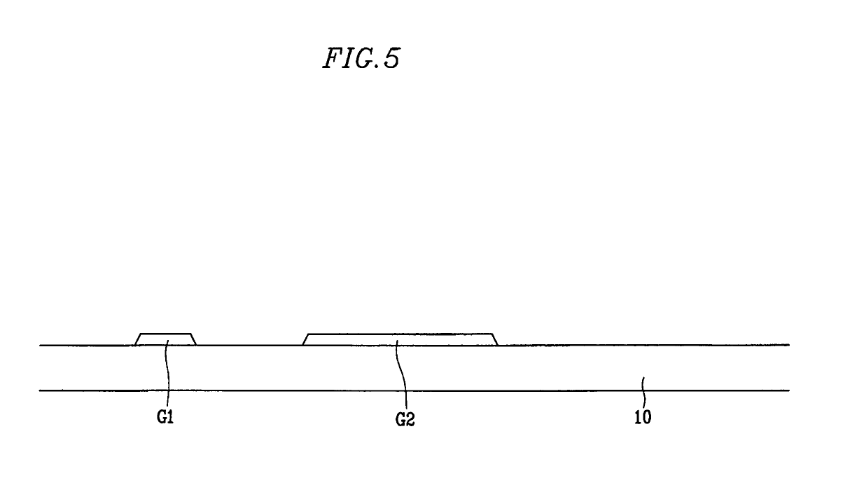

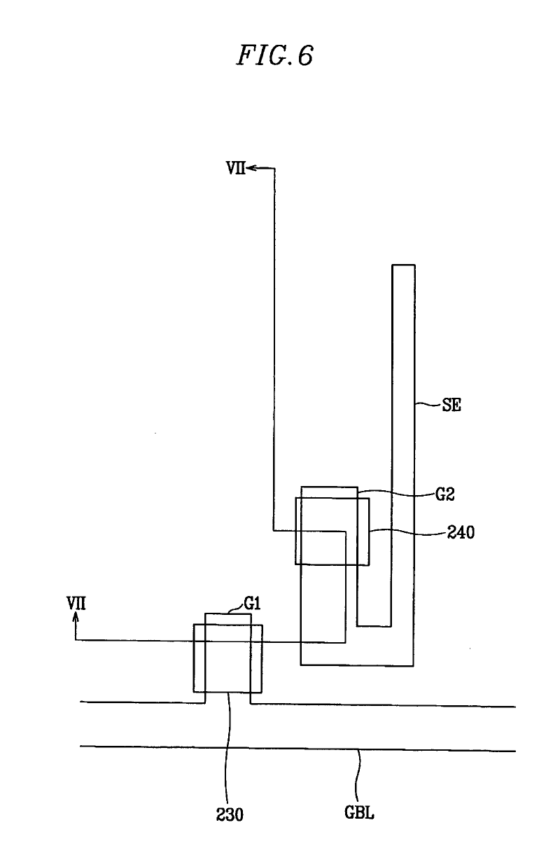

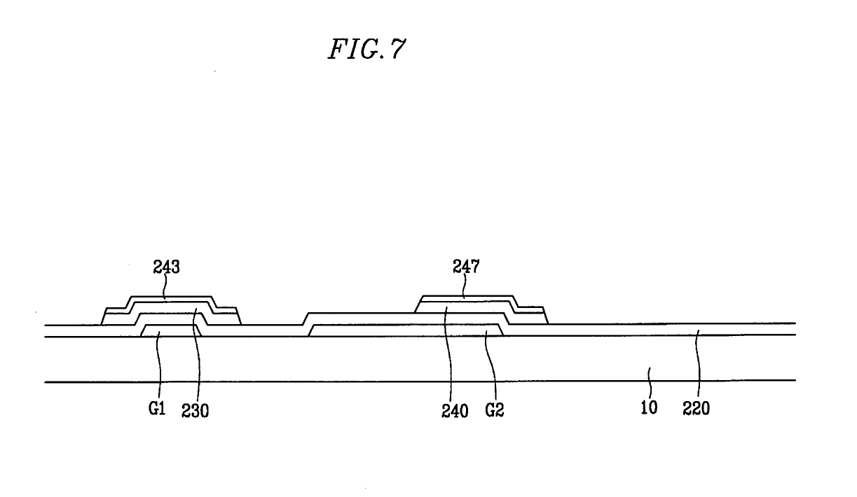

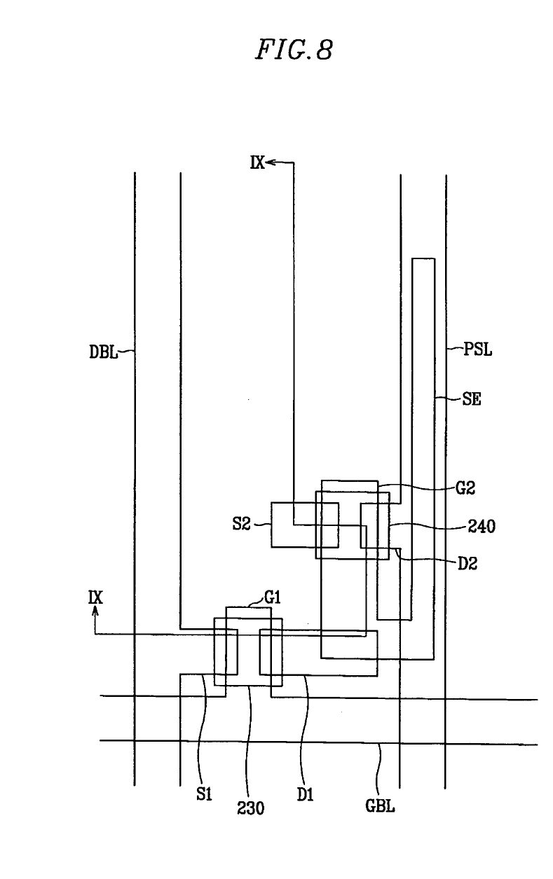

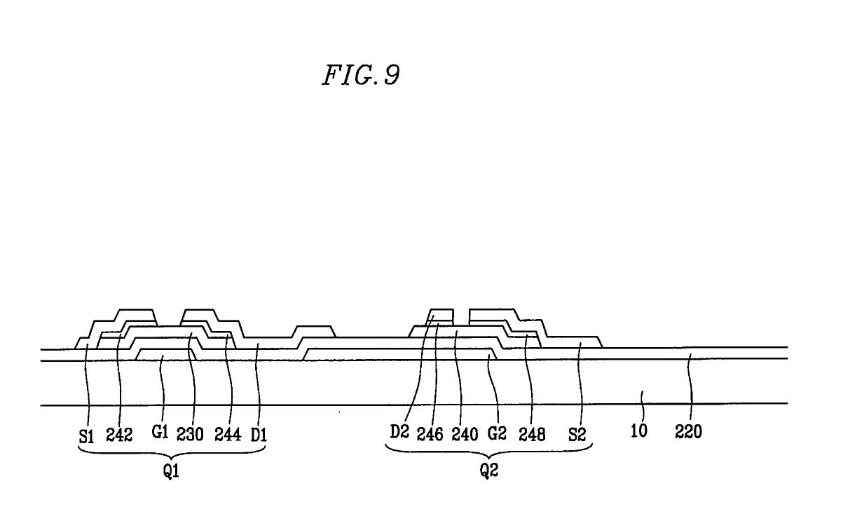

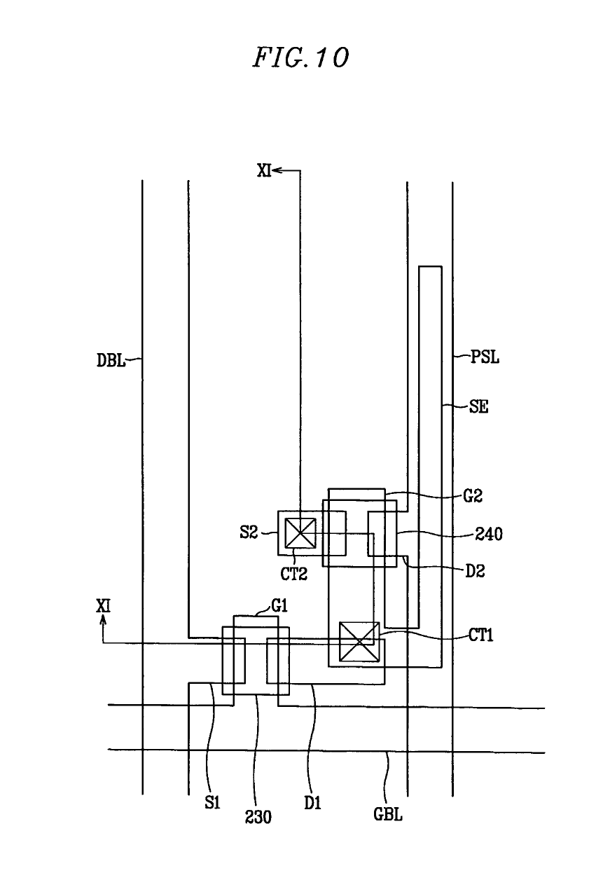

FIG. 4, FIG. 6, FIG. 8, FIG. 10, and FIG. 15 are layout views of the OLED display of FIG. 2 and FIG. 3 in intermediate steps of a manufacturing method thereof according to an embodiment of the present invention, and FIG. 5, FIG. 7, FIG. 9, FIG. 11 and FIG. 16 are sectional views of the OLED display along lines V-V, VII-VII, IX-IX, XI-XI and XVI-XVI of FIG. 4, FIG. 6, FIG. 8, FIG. 10, and FIG. 15, respectively.

Referring to FIG. 4 and FIG. 5, a gate metal film (not shown) may be deposited by CVD or sputtering on a substrate such as transparent glass. The gate metal film is then patterned to form a plurality of gate conductors including a plurality of gate bus lines GBL having first gate electrodes G1 and a plurality of second gate electrodes G2 having storage electrodes SE.

Referring to FIG. 6 and FIG. 7, after sequentially depositing a first insulating layer 220, which may be made of an insulator such as SiNx and SiOx, or a high dielectric such as HfO₂ and Al₂O₃, an intrinsic a-Si layer, and an extrinsic a-Si layer using CVD, the extrinsic a-Si layer and the intrinsic a-Si layer may be photo-etched to form a plurality of extrinsic semiconductor islands 243 and 247 and a plurality of intrinsic semiconductor islands 230 and 240 on the first insulating layer 220.

Referring to FIG. 8 and FIG. 9, a conductive layer may be sputtered or deposited by CVD and photo-etched to form a plurality of data conductors including a plurality of data bus lines DBL having first source electrodes S1, a plurality of voltage transmission lines PSL having second drain electrodes D2, a plurality of first drain electrodes D1, and a plurality of second source electrodes S2. At this time, portions of extrinsic semiconductor islands 243 and 247 disposed between the first source electrodes S1 and the first drain electrodes D1 and between the second source electrodes S2 and the second drain electrodes D2 are exposed.

The exposed portions of the extrinsic semiconductor islands 243 and 247, which are not covered with the data conductors DBL, PSL, D1 and S2, may be removed by etching to complete a plurality of ohmic contact islands 242, 244, 246 and 248 and to expose portions of the intrinsic semiconductor islands 230 and 240. Oxygen plasma treatment may follow thereafter in order to stabilize the exposed surfaces of the semiconductor islands 230 and 240.

Accordingly, the switching transistor Q1 and the driving transistor Q2 are completed.

Referring to FIG. 10 and FIG. 11, a second insulating layer 340 may be deposited by CVD, etc., and patterned along with the first insulating layer 220 to form a plurality of contact holes CT1, which expose portions of the first drain electrodes D1 and the second gate electrodes G2, and a plurality of contact holes CT2, which expose portions of the second source electrodes S2.

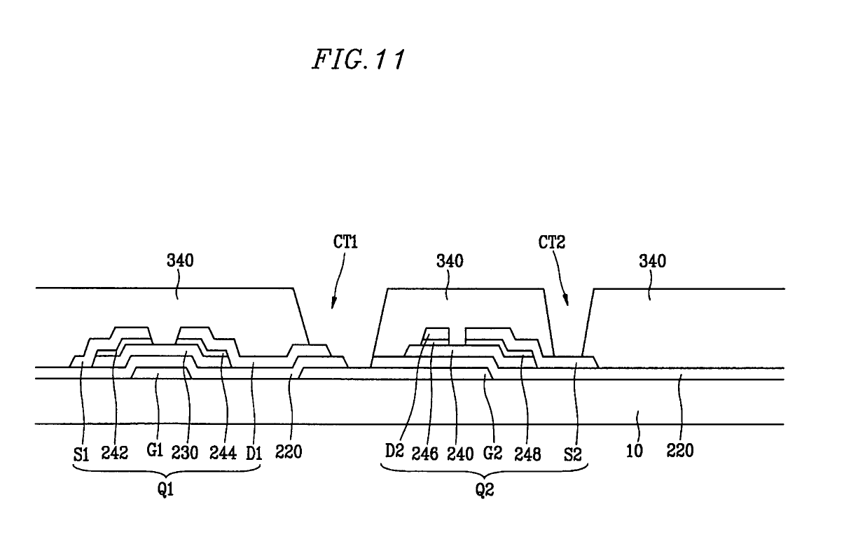

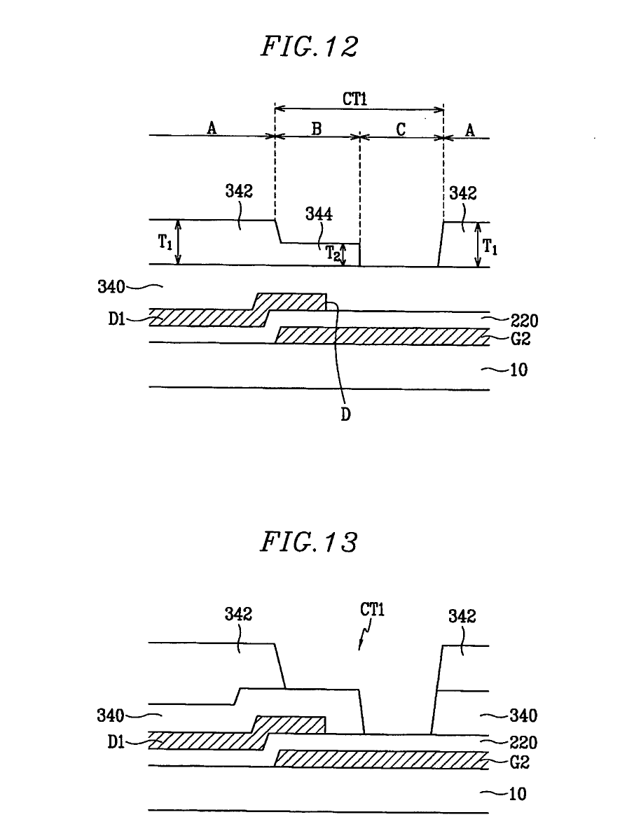

Here, the first contact holes CT1 expose an edge of the first drain electrodes D1, portions of the first insulating layer 220 adjacent thereto, and the second gate electrodes G2, which will be described in detail below with reference to FIG. 12, FIG. 13 and FIG. 14.

Referring to FIG. 12, a photoresist having position-dependent thickness is formed on the second insulating layer 340. The photoresist includes first portions 342 and second portions 344. The first portions 342 have a thickness T1 and cover areas A, which include all of the substrate except for the area corresponding to the first contact holes CT1. The second portions 344 have a thickness T2 that is less than the thickness T1, and each second portion 344 is disposed on area B of the area corresponding to the first contact hole CT1. Area B includes an edge D of the first drain electrode D1. Photoresist is not formed on area C, which is the remainder of the area corresponding to the contact hole CT1.

The photoresist's position-dependent thickness may be obtained by several techniques. For example, translucent areas may be provided on the exposure mask as well as light transmitting areas and light blocking opaque areas. The translucent areas may have a slit pattern, a lattice pattern, a thin film(s) with intermediate transmittance or intermediate thickness. When using a slit pattern, the width of the slits or the distance between the slits may be smaller than the resolution of a light exposer used for the photolithography. Another example is to use reflowable photoresist. In detail, once a photoresist pattern made of a reflowable material is formed by using a normal exposure mask with transparent areas and opaque areas only, it is subject to reflow process to flow onto areas without the photoresist, thereby forming thin portions.

Referring to FIG. 13, exposed portions of the second insulating layer 340 are removed by using the photoresist 342 and 344 as an etch mask, thereby exposing the first insulating layer 220. Thereafter, thin portions 344 of the photoresist are removed to expose underlying portions of the second insulating layer 340.

Referring to FIG. 14, the exposed portions of the second insulating layer 340 and the first insulating layer 220 are removed to expose the first drain electrodes D1 and the second gate electrodes G2. Here, the end point of etching is selected to be a time when the first drain electrodes D1 and the second gate electrodes G2 are exposed so that portions of the first insulating layer 220 near edges D of the first drain electrodes D1 may not be removed. In other words, edges E of the first insulating layer 220 extend beyond edges D of the first drain electrodes D1, or the edges D of the first drain electrodes D1 are disposed on the first insulating layer 220. This is to prevent an undercut where portions of the first insulating layer 220 disposed under the first drain electrodes D1 are removed when portions of the first insulating layer 220 near the edges D of the first drain electrodes D1 are removed.

The second insulating layer 340, the thin portions 344 of the photoresist, and the first insulating layer 220 may be etched in sequence. A condition where the photoresist 342 and 344 and the insulating layers 220 and 340 are simultaneously etched may be selected. In this case, the thickness T1 of the thick portions 342 may be reduced, and it is preferable that the thickness T1 is determined so that the thick portions 342 are not removed until the first drain electrodes D1 and the second gate electrodes G2 are exposed. The thickness of the photoresist 342 and 344 may be adjusted by controlling the exposure time, the light amount, or the etch selectivity between the photoresist and the first and the second insulating layers.

Referring to FIG. 15 and FIG. 16, a transparent conductive film may be deposited on the second insulating layer 340 by sputtering, etc., and then photo-etched to form a plurality of pixel electrodes 310 and a plurality of connecting members 305. The pixel electrodes 310 are coupled to the second source electrodes S2 through the second contact holes CT2, and the connecting members 305 are coupled to the first drain electrodes D1 and the second gate electrodes G2 in the first contact holes CT1. Here, if an undercut exists under the first drain electrodes D1 at the first contact holes CT1, the connecting members 305 may be disconnected there. However, in this embodiment, the first insulating layer 220 extends beyond edges D of the first drain electrodes D1 to form a stepwise profile, thereby preventing the undercut problem and resulting disconnection of the connecting members 305.

Referring to FIG. 2 and FIG. 3 again, an inorganic or organic insulator may be deposited and patterned to form a bank 350 partly exposing the pixel electrodes 310.

A plurality of organic light emitting members 320 capable of emitting red, green, or blue light are formed on the pixel electrodes 310, and a common electrode 330 is formed thereon. In this embodiment, the pixel electrode 310 is made of transparent ITO or IZO to inject holes in the light emitting member 320, and the common electrode 330 is made of at least one of Al, Ca, Ba and Mg to inject electrons into the light emitting member 320.

An encapsulation or a protection layer (not shown) may be formed on the common electrode 330 to protect the organic light emitting members 320 from oxidation or moisture. The protection layer may be made of organic material, inorganic material, or their laminations.

Next, an OLED display according to another embodiment of the present invention will be described in detail.

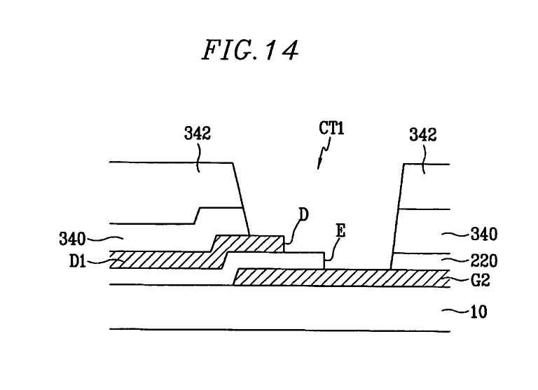

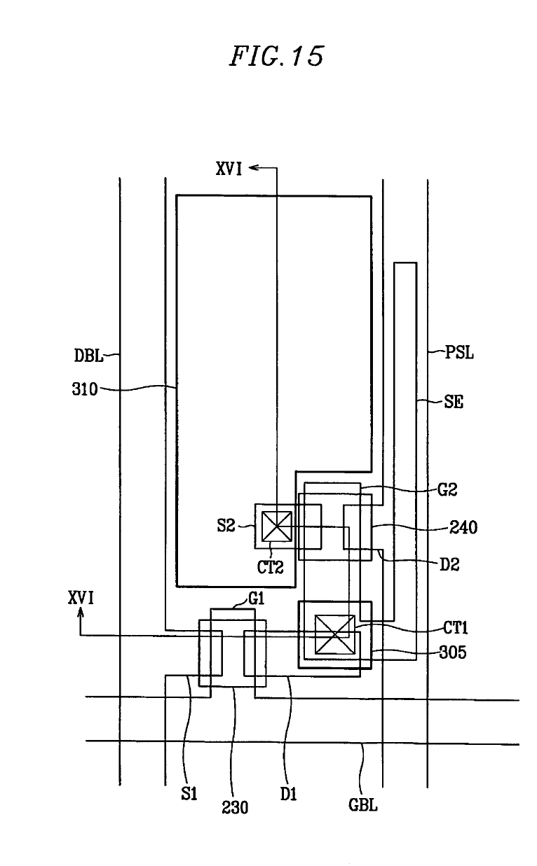

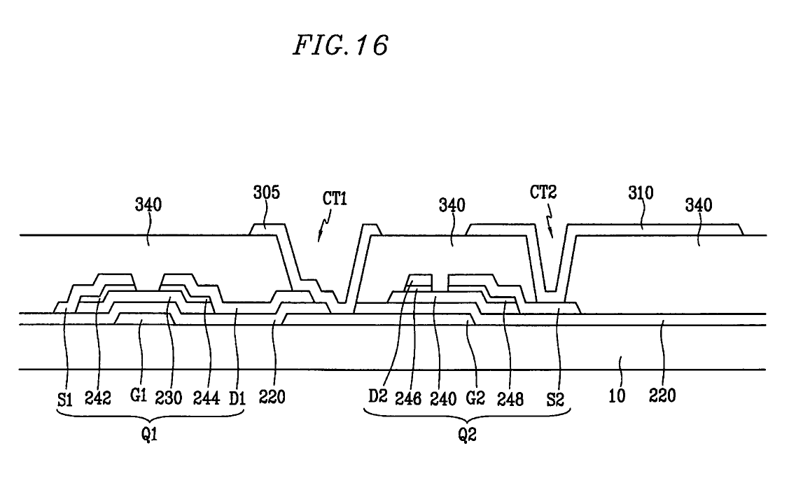

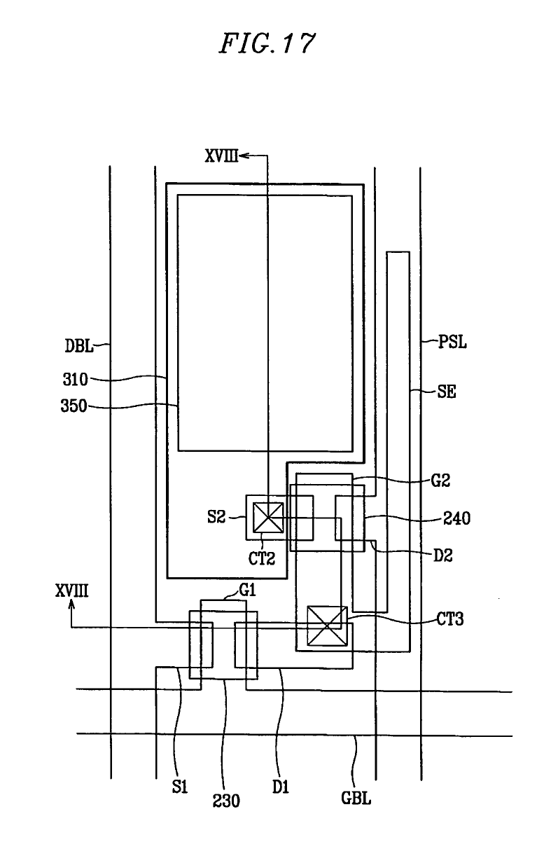

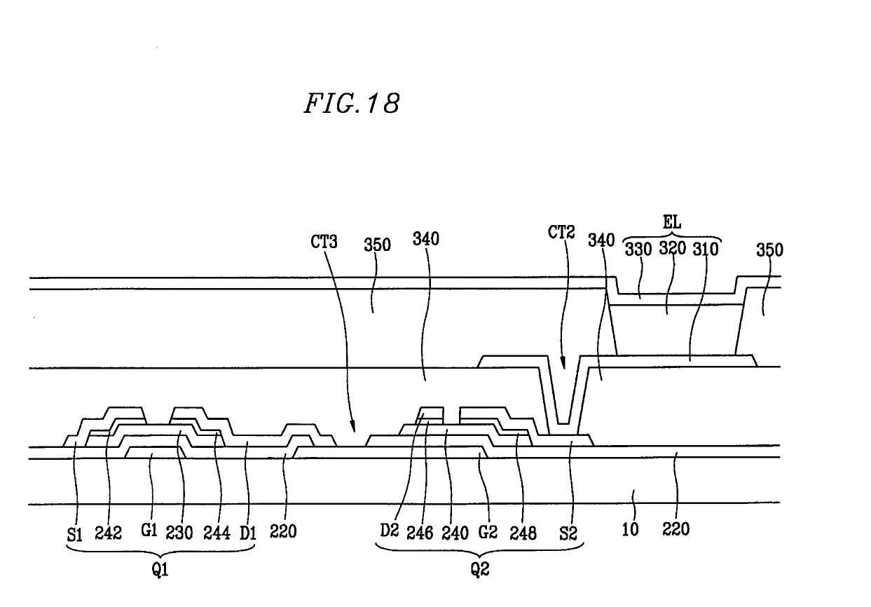

FIG. 17 is a layout view of an OLED display according to another embodiment of the present invention, and FIG. 18 is a sectional view of the OLED display along line XVIII-XVIII of FIG. 17.

Referring to FIG. 17 and FIG. 18, a layered structure of the OLED display according to this embodiment is similar to that shown in FIG. 2 and FIG. 3.

That is, a plurality of gate bus lines GBL having gate electrodes G1 and a plurality of second gate electrodes G2 having storage electrodes SE are formed on a substrate 10, and a first insulating layer 220, a plurality of first and second semiconductor islands 230 and 240, and a plurality of first to fourth ohmic contacts 242, 244, 246 and 248 are sequentially formed thereon. A plurality of data bus lines DBL having first source electrodes S1, a plurality of first drain electrodes D1, a plurality of voltage transmission lines PSL having second drain electrodes D2, and a plurality of second source electrodes S2 are formed on the ohmic contacts 242, 244, 246 and 248 and the first insulating layer 220, and a second insulating layer 340 is formed thereon. A plurality of contact holes CT2 exposing portions of the second source electrodes S2, and a plurality of pixel electrodes 310 are formed on the second insulating layer 340. A bank 350, a plurality of organic light emitting members 320, and a common electrode 330 are formed on the second insulating layer 340 and the pixel electrodes 310. 100881 Unlike the OLED display of FIG. 2 and FIG. 3, the first insulating layer 220 of the OLED display according to this embodiment has a plurality of contact holes CT3 exposing the second gate electrodes G2, and the first drain electrodes D1 contact the second gate electrodes G2 through the contact holes CT3. Additionally, there is no connection member in this embodiment.

Many of the above-described features of the OLED display shown in FIG. 2 and FIG. 3 may be appropriate to the OLED display of FIG. 17 and FIG. 18.

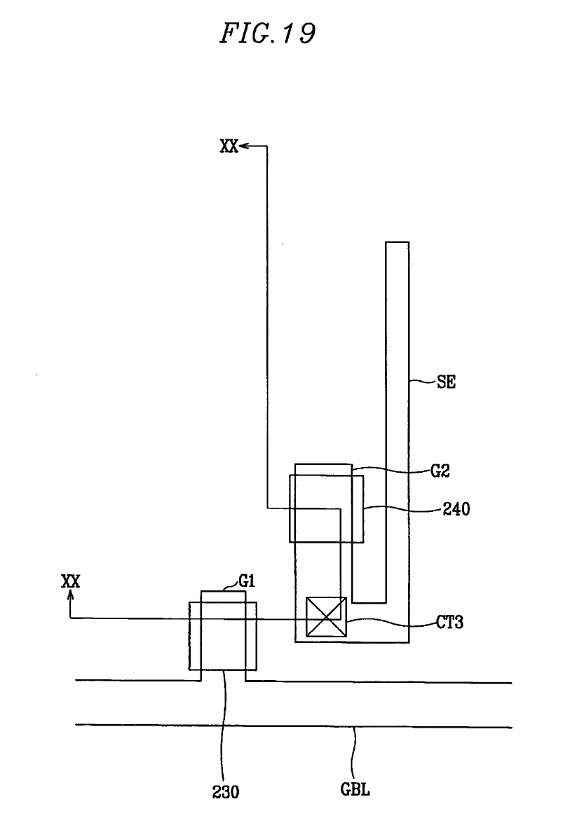

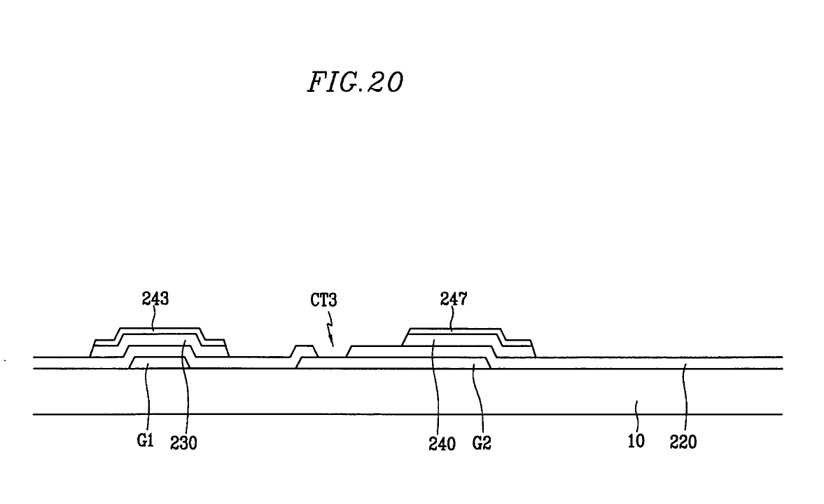

A method of manufacturing the OLED display of FIG. 17 and FIG. 18 according to an embodiment of the present invention will be described below in detail with reference to FIG. 19 and FIG. 20, as well as FIG. 17 and FIG. 18.

FIG. 19 is a layout view of the OLED display of FIG. 17 and FIG. 18 in an intermediate step of a manufacturing method thereof according to an embodiment of the present invention, and FIG. 20 is a sectional view of the OLED display along line XX-XX of FIG. 19.

Referring to FIG. 19 and FIG. 20, a plurality of gate bus lines GBL including first gate electrodes G1, and a plurality of second gate electrodes G2 including storage electrodes SE, are formed on a substrate 10.

A first insulating layer 220, an intrinsic a-Si layer, and an extrinsic a-Si layer may be sequentially deposited using CVD. As described above with reference to FIG. 12, FIG. 13, and FIG. 14, a photoresist (not shown) including two portions with different thickness is formed using a photo mask provided with slits, etc. The three layers are etched to form a plurality of contact holes CT3, a plurality of intrinsic semiconductor islands 230 and 240, and a plurality of extrinsic semiconductor islands 243 and 247. At this time, there is no photoresist on areas corresponding to the contact holes CT3. Additionally, the thick portions of the photoresist are disposed on areas corresponding to the intrinsic semiconductor islands 230 and 240 and the extrinsic semiconductor islands 243 and 247, and the thin portions of the photoresist are disposed on the remaining portions. Appropriate selection of the thickness of the photoresist allows selective etching the first insulating layer 220, the intrinsic a-Si layer, and the extrinsic a-Si layer. As a result, the first insulating layer 220 may be selectively etched to form the contact holes CT3 without etching other portions of the first insulating layer 220, as shown in FIG. 20.

Next, as shown in FIG. 17, a plurality of data bus lines DBL including first source electrodes S1, a plurality of first drain electrodes D1, a plurality of second source electrodes S2, and a plurality of voltage transmission lines PSL including second drain electrodes D2 are formed. In this case, the first drain electrodes D1 include portions contacting the second gate electrodes G2 through the contact holes CT3.

Subsequently, a second insulating layer 340 having contact holes CT2, a plurality of pixel electrodes 310, a bank 350, a plurality of organic light emitting members 320, and a common electrode 330 are formed as described above.

As described above, a drain electrode of the switching transistor is coupled to a gate electrode of the driving transistor through one contact hole, thereby reducing the area for coupling the two electrodes and increasing the aperture ratio.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A light emitting diode display, comprising:
a light emitting element;
a first conductive line, a second conductive line, and a third conductive line separated from one another; and
a first thin film transistor coupled to the third conductive line and the light emitting element and a second thin film transistor coupled to the first conductive line and the second conductive line,
wherein a third thin film transistor includes a first electrode and a fourth thin film transistor includes a second electrode, and the first electrode and the second electrode are coupled to each other through a first contact hole in a first insulating layer.

2. The light emitting diode display of claim 1, wherein the first electrode is arranged under the first insulating layer, and the second electrode is arranged on the first insulating layer and covered with a second insulating layer that has a second contact hole exposing the first contact hole and the second electrode at least in part.

3. The light emitting diode display of claim 2, wherein the second electrode overlaps the first electrode in the second contact hole.

4. The light emitting diode display of claim 3, wherein the second contact hole exposes a portion of the first insulating layer near an edge of the second electrode.

5. The light emitting diode display of claim 2, further comprising a connecting member coupled to the first electrode and the second electrode through the first contact hole and the second contact hole.

6. The light emitting diode display of claim 5, wherein a stepwise profile is formed from the second electrode to the first electrode.

7. The light emitting diode display of claim 5, wherein the light emitting element comprises:
a pixel electrode coupled to the first thin film transistor;
a light emitting member formed on the pixel electrode; and
a common electrode formed on the light emitting member.

8. The light emitting diode display of claim 7, wherein the connecting member is formed of the same layer as the pixel electrode.

9. The light emitting diode display of claim 7, wherein the light emitting member comprises organic material.

10. The light emitting diode display of claim 7, further comprising a bank formed on the pixel electrode, wherein the light emitting member is formed in an opening in the bank.

11. The light emitting diode display of claim 1, wherein the first thin film transistor and the third thin film transistor are the same transistor, and the second thin film transistor and the fourth thin film transistor are the same transistor.

12. The light emitting diode display of claim 11, wherein the second thin film transistor further comprises a third electrode coupled to the first conductive line and a fourth electrode coupled to the second conductive line, and outputs a data signal through the second electrode in response to a timing signal, the data signal being applied to the fourth electrode through the second conductive line and the timing signal being applied to the third electrode through the first conductive line, and
the first thin film transistor further comprises a fifth electrode coupled to the third conductive line and a sixth electrode coupled to the light emitting element, and outputs a driving current through the sixth electrode based on a level of the data signal applied to the first electrode.

13. The light emitting diode display of claim 12, wherein the light emitting element comprises:
a first display electrode receiving the driving current from the first thin film transistor;
an organic light emitting member coupled to the first display electrode; and
a second display electrode coupled to the organic light emitting member,
wherein the first display electrode and the second display electrode supply the organic light emitting member with electric charges and the organic light emitting member emits light based on the electric charges.

14. The light emitting diode display of claim 13, wherein the third conductive line transmits a voltage.

15. The light emitting diode display of claim 14, further comprising a storage capacitor that is coupled between the fifth electrode and the first electrode and that stores and maintains a difference between the data signal and the voltage from the third conductive line.

16. The light emitting diode display of claim 1, wherein the first electrode and the second electrode contact each other through the first contact hole.

17. The light emitting diode display of claim 1, wherein the first insulating layer is interposed between the first electrode and the second electrode.

18. A thin film panel, comprising:
a substrate;
a first conductive layer formed on the substrate;
a first insulation layer formed on the first conductive layer;
a second conductive layer formed on the first insulation layer;
a second insulation layer formed on the second conductive layer;
a contact hole formed in the first insulation layer and the second insulation layer and exposing at least a portion of the first conductive layer and at least a portion of the second conductive layer; and
a third conductive layer formed in the contact hole and coupling the first conductive layer to the second conductive layer.

19. The thin film panel of claim 18, wherein the thin film panel comprises an organic light emitting diode display panel.

20. A method for manufacturing an organic light emitting diode display, comprising:
forming a first gate electrode and a second gate electrode on a substrate;
forming a first insulator on the first gate electrode and the second gate electrode;
forming a first semiconductor and a second semiconductor on the first insulator, the first semiconductor and the second semiconductor overlapping the first gate electrode and the second gate electrode, respectively;
forming a first source electrode and a first drain electrode on the first semiconductor and spaced apart from each other, and a second source electrode and a second drain electrode on the second semiconductor and spaced apart from each other;
depositing a second insulator;
etching the second insulator and the first insulator to form a contact hole exposing the second gate electrode and the first drain electrode at least in part; and
forming a connecting member coupling the second gate electrode with the first drain electrode through the contact hole.

21. The method of claim 20, further comprising forming an organic light emitting element on the second insulator, wherein the organic light emitting element is coupled to the second source electrode.

22. The method of claim 20, wherein the first drain electrode overlaps the second gate electrode.

23. The method of claim 20, wherein etching the second insulator and the first insulator to form the contact hole comprises:
performing lithography with a photoresist including a first portion and a second portion, the first portion covering the substrate except for the contact hole and the second portion corresponding to an edge of the first drain electrode in the contact hole,
wherein the first portion is thicker than the second portion.

24. The method of claim 23, wherein the lithography comprises:
forming the photoresist by light exposure with one photo mask.

25. A method for manufacturing an organic light emitting diode display, comprising:
forming a first gate electrode and a second gate electrode on a substrate;
forming a first insulating layer on the first gate electrode and the second gate electrode;
forming a first semiconductor and a second semiconductor on the first insulating layer, the first semiconductor and the second semiconductor overlapping the first gate electrode and the second gate electrode, respectively;
forming a contact hole in the first insulating layer, the contact hole exposing a portion of the second gate electrode; and
forming a first drain electrode and a first source electrode on the first semiconductor and a second drain electrode and a second source electrode on the second semiconductor, the first drain electrode being coupled to the second gate electrode through the contact hole.

26. The method of claim 25, further comprising:
forming a second insulating layer; and
forming an organic light emitting element on the second insulating layer,
wherein the organic light emitting element is coupled to the second source electrode.
